(19) United States
(12) Patent Application Publication
(10) Pub. No.: US 2003/0001223 A1
(43) Pub. Date: Jan. 2, 2003

(54) Circuit layout for several sensor elements

(76) Inventor: Oliver Gremm, Kurnbach (DE)

Correspondence Address: LAW OFFICES OF DICK AND HARRIS, Suite 3800, 181 West Madison Street, Chicago, IL, 60602, US

(21) Appl. No.: 10/158,638

(22) Filed: May 30, 2002

(30) Foreign Application Priority Data
May 30, 2001 (DE) 10127595.1

(51) Int. Cl. H01L 31/00

(52) U.S. Cl. 257/444

(57) ABSTRACT

A circuit layout for several sensor elements of touch switches is described. It is subdivided into a control part with a control signal and a sensor part with several sensor branches, which in each case contain a capacitive sensor element. An evaluating part inter alia has a capacitor, where an analog output signal can be tapped. By means of connecting means, e.g. in the form of transistors or diodes, with a corresponding control in each case precisely one sensor branch is connected to the remaining circuit and the corresponding sensor element is controlled and evaluated.

### FIELD OF APPLICATION AND PRIOR ART

The invention relates to a circuit layout for several sensor elements of several touch switches, the sensor elements having an operating state that changes as a consequence of operation.

Such circuit layouts are known from the prior art, e.g. from EP 859 648. In the latter the sensor elements are permanently connected to the control means or the control signal is permanently applied. They are also permanently connected to the evaluating means, evaluation of the individual sensor elements taking place by means of a multiplexer. Thus, certain costs are involved with the said circuit layout, which prevent a more widespread use of touch switches.

### PROBLEM AND SOLUTION

The problem of the invention is to provide a circuit layout for several sensor elements, which is simplified from the circuitry standpoint or can be implemented with lower component costs and which ensures reliable operation.

This problem is solved by a circuit layout having the features of claim 1. Advantageous and preferred developments of the invention form the subject matter of the further claims and are described in greater detail hereinafter. By express reference the wording of the claims is made into part of the content of the description. In the context of this application the word comprise is not to be understood as limited to, but including.

According to the invention connecting means or connecting switching means are provided, with which a sensor element is connected or interconnected with the evaluating part for the evaluation of an operating state. This connection or interconnection can be selectable, so as in this way to bring about an adaptation to different circumstances, as well as the number of sensor elements. Particular preference is given to a sensor element connected to the evaluating part, so that the latter can be kept very simple. This avoids complicated components or a multiplexer, as described in EP 859 468.

The connecting means can be constituted by semiconductor components. In a particularly simple version they can be diodes. However, it is also advantageous to use switching means or controllable, particularly electronically controllable switches, for which transistors represent a good choice.

The connecting means are advantageously controlled by means of a signal, preferably a timed signal. A timing means can be designed in such a way that in each case only one sensor element is simultaneously connected across the connecting means to the evaluating part. According to a further development of the invention, for each sensor element a connecting switching means is provided, which enables a simplification of the circuit.

According to a design possibility provided by the invention, the control signal can be permanently applied to the sensor elements or the latter can be connected to the control signal.

In another preferred design possibility, the sensor elements are connected by connecting means to the control signal. Preferably they are the same connecting means as are used for connecting to the evaluating part.

An evaluating part of a circuit layout can be constructed in such a way that it has a capacitor and a transistor. The transistor collector can be connected across the capacitor to earth or ground. The emitter can be connected to the control signal. The transistor base can be connected across a diode and a resistor to a control signal. Advantageously an equilibrium between the base and emitter occurs during the operation of the circuit across the resistor and the diode when the sensor element connected to the evaluating part is not in operation. This should be a voltage equilibrium. Advantageously the evaluating part is connected to a controller for evaluating the signal, so that as a function thereof a switching process or a state change can be brought about.

On operating the sensor element, in the case of the aforementioned construction the equilibrium between the transistor base and the emitter can be modified. The transistor opens more strongly and the capacitor can be charged to a higher voltage value. In such a case the transistor advantageously operates as a resistor controllable across its base. This increased voltage value can be evaluated by means of a simple follow-up circuit, because the signal change can be selected relatively high.

The sensor elements of the circuit layout can be contained in independent sensor branches. One sensor branch can in each case contain a control point and a mass or body contact. The control point can be connected to the control signal or control circuit and simultaneously the evaluating circuit. The connecting switching means are preferably contained in the sensor branch. In particular, there is also a control associated with the connecting switching means in each sensor branch or is separately provided for the same.

As a result of the simplified construction of the circuit according to the invention, it is possible to arrange the sensor elements further apart whilst simultaneously obtaining a very good signal travel and for this purpose no analog switch components are needed. In addition, the signal travel of the circuit can be made so large that it is possible to evaluate a signal of a sensor element without amplifiers. Several or many sensor elements can be operated with a minimum of components. By means of the connecting switching means a type of multiplexing can take place, but of a very simple and convincing nature from the circuitry standpoint.

These and further features can be gathered from the claims, description and drawings and the individual features, both singly and in the form of subcombinations, can be implemented in an embodiment of the invention and in other fields and can represent advantageous, independently protectable constructions for which protection is hereby claimed. The subdivision of the application into individual sections and the subheadings in no way limit the general validity of the statements made thereunder.

### BRIEF DESCRIPTION OF THE DRAWINGS

Embodiments of the invention are described hereinafter relative to the attaching drawings, wherein show:

FIG. 1 A fundamental variant of a circuit layout in which transistors are used as connecting switching means.

FIG. 2 A circuit layout similar to FIG. 1, in which diodes are used as connecting means.

FIG. 3 A further variant of the circuit layout.

FIGS. 4 to 7 Variants of the circuit layout of FIG. 3.

### DETAILED DESCRIPTION OF THE EMBODIMENTS

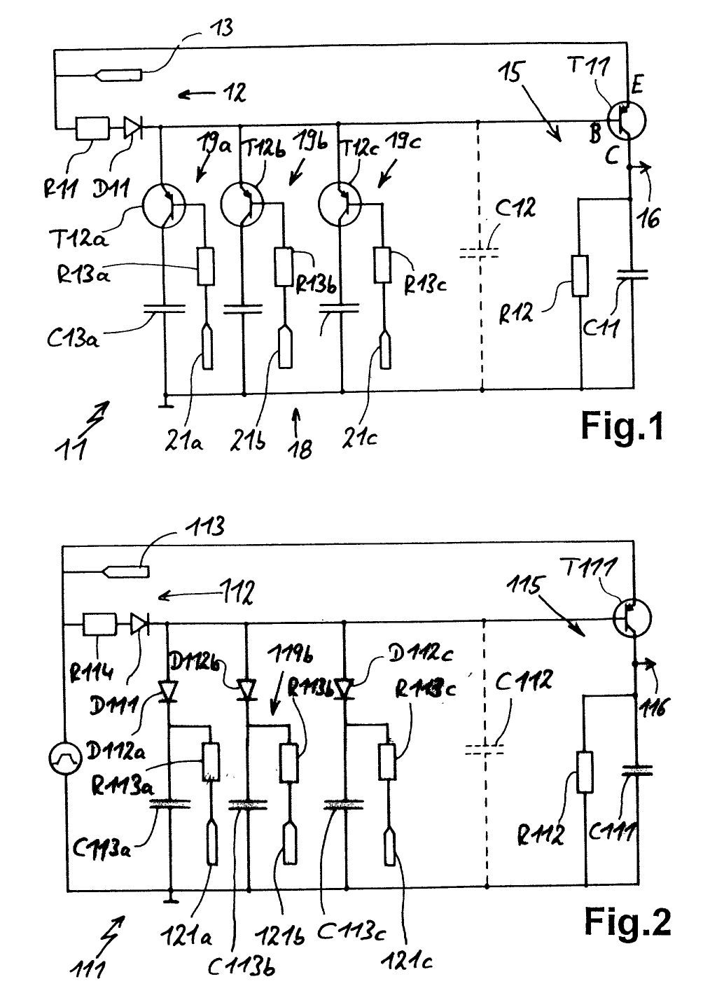

FIG. 1 shows a circuit layout, which is designed in exemplified manner for the evaluation of three capacitive touch switches. In a simple modification, it is obviously possible to operate further touch switches. A control part 12 of the circuit 11 has a signal source 13 with a control signal. The control signal is preferably an alternating voltage signal or a unipolar square-wave signal. There are also a resistor R11 and a diode D11 in the control part 12.

The evaluating part 15 has a transistor T11, whose emitter E is connected to the signal source 13 and whose base B is connected to the diode D11. The collector C of T11 is placed against the basic potential of the circuit or ground by means of a parallel connection of a capacitor C11 and a resistor R12. By means of an output 16 it is possible to tap the output signal, which is applied as an analog signal to the capacitor C11.

The capacitor C12 constitutes a disturbance variable in the circuit and can be inserted in a circuit for a homogeneous output signal. Fundamentally such a disturbance variable should be avoided, but through component insertion the satisfactory function of the circuit can be ensured. An exemplified value for C12 is approximately 10 pF. A R disturbance variable or a RC disturbance variable are also possible.

The sensor part 18 of the circuit layout 11 comprises several so-called sensor branches 19, which have in each case a capacitive touch switch C13a-c and are represented by a capacitor. It is possible to use as capacitive touch switches all possible types, particularly preference being given to those described in EP 98101516, whose content is hereby made by express reference into part of the content of the present patent application.

The sensor branches 19 also have connecting switching means in the form of transistors T12a-c, whose function is to connect the touch switches C13 with the control part 12 and evaluating part 15. The transistors T12a-c are controlled via connecting switching signals 21 and series resistors 22. The connecting switching signals 21 are selected in such a way that at all times only one sensor branch 19 is at the control part 12 and evaluating part 15.

### FUNCTION OF THE CIRCUIT IN FIG. 1

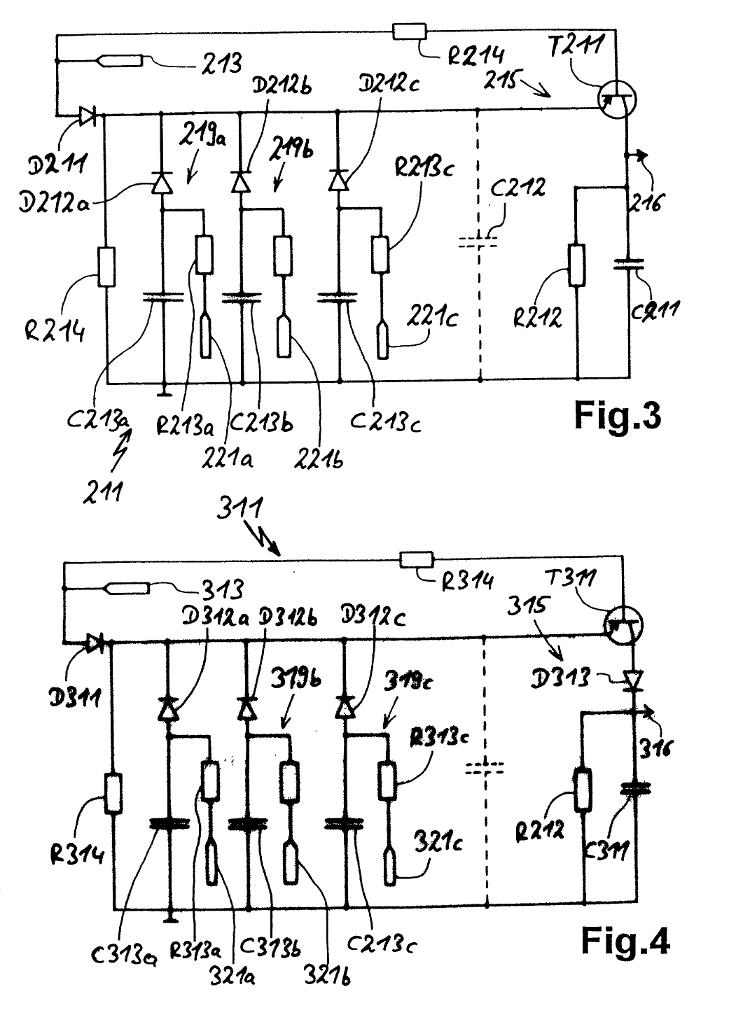

The fundamental function of the circuit of FIG. 1 will now be described. This description generally applies to the other circuits according to FIGS. 2 to 7 and any differences will in each case be explained.

The signal source 13 for control purposes supplies a control signal, which is applied to the emitter E of T11 and via the diode branch to the base B of T11. By means of the connecting switching signals 21 in an automatic, predetermined order individual sensor branches 19 and therefore sensor elements C13 are connected to the circuit. In exemplified manner, hereinafter the case is used as a basis where the sensor branch 19 is connected across the controlled transistor T12a. If the touch switch C13a is not operated, across the diode D11 there is a synchronization between emitter E and base B of T11.

If the touch switch C13a is now operated, this leads to a voltage or transit time change at base B compared with the emitter E of T11. This leads to a greater opening of transistor T11 and the evaluating capacitor C11 is charged to the higher voltage value. T11 acts as a variable resistor controlled across its base. The output signal can be taken from the capacitor C11 via the output 16. It can be evaluated e.g. by a controller or the like. Such an evaluating method is described in the aforementioned European patent application. On opening transistor T11, C11 is charged. Across resistor R12, C11 can be discharged again if the control signal of signal source 13 is zero.

Through the successive connection or coupling of in each case one sensor branch 19 to the control or evaluating circuit, there is a type of timed polling of the individual sensor branches. This permits a very simple control of several sensor elements C13, whose switching state is polled successively or in timed manner by the connecting switching signals 21.

### DESCRIPTION OF THE OTHER CIRCUIT EXAMPLES

FIG. 2 shows a slight modification of the circuit of FIG. 1, the connecting switching means T12 constructed as freely switchable transistors being replaced by connecting means in the form of diodes D12. Through a corresponding choice of the connecting switching signals, in precisely the same way as for the circuit of FIG. 1, in each case one sensor branch 119 can be connected to the remaining circuit.

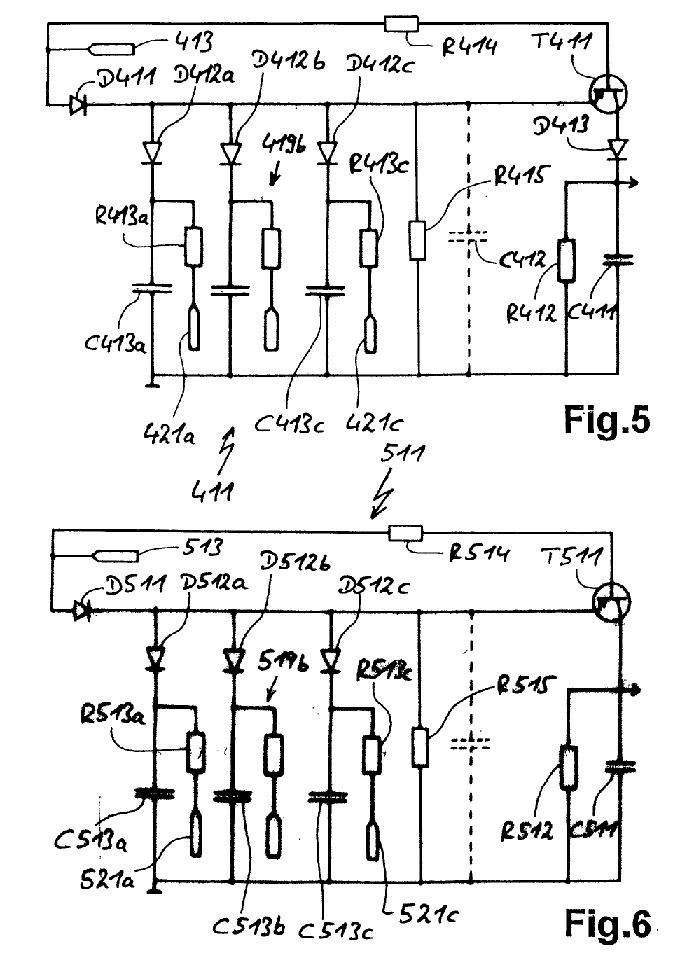

The circuit 211 in FIG. 3 is a further modification. The fundamental structure with control part 212, evaluating part 215 and sensor branches 219 is also present here. For example, three sensor branches 319a-c are shown, but there can be a random greater number. As a variant the resistor R214 is placed between the signal source 213 and the base B of transistor T211. The emitter E is connected across the diode D211 to the control signal 213.

The sensor branches 219a-c are constructed in substantially the same way as in FIG. 2, but the diodes are oppositely connected. There is also a resistor R214 parallel to the sensor branches 219. Said resistor R214 functions as a leakage resistor and discharges the sensor elements C213 and renders the diodes D212 conductive.

### FUNCTION OF THE CIRCUIT LAYOUT IN FIG. 3

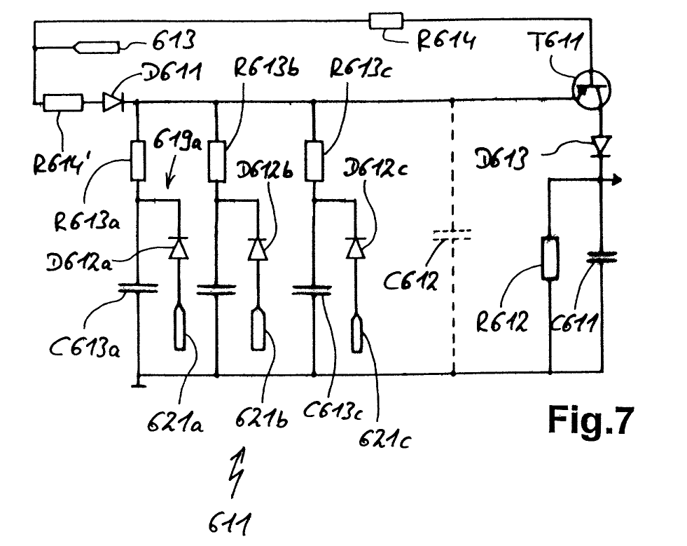

Hereinafter the function of the circuit layout of FIG. 3 is described. This also applies to the further variants of said circuit in FIGS. 4 to 7.

The signal source 213 supplies an alternating voltage or unipolar square-wave signal, which is fed across resistor R214 to the base B of T211. The control signal is applied to the emitter E of T211 across diode D211. During the time where the control signal is higher than 0.7 V, in the case of an operated sensor element capacitor C213, the latter is charged to the value (control signal-0.7 V). During this time the transistor T211 is blocked, in order to separate the area of the evaluating part 215 with output 216 and capacitor 211.

At the time where the input voltage of the control signal 213 drops below the voltage at emitter E of T211, the diode T212 is blocked, the transistor T211 is opened and transfers the voltage at sensor element 213 to capacitor C211 of the evaluating part. As described hereinbefore, as a result the analog output signal can be tapped at the output 216. An actuation can be read from this output signal. It must be borne in mind that via the connecting switching signals 211 and the resistor R214 in each case precisely only one diode 212 can be made conductive and consequently said sensor branch 219 is connected to the remaining circuit.

### DESCRIPTION OF THE EMBODIMENTS ACCORDING TO FIGS. 4-7

The circuit according to FIG. 4 corresponds to that of FIG. 3. However, there is additionally a diode D313 between the collector C of T311 and the parallel branch of capacitor T311 and R312. This diode avoids a leakage current between D311 and T311.

The circuit of FIG. 5 corresponds to that of FIG. 4, but here again the diodes D412 are turned around. Resistor R415 can symbolize further disturbance variables.

The circuit of FIG. 6 corresponds to that of FIG. 5, but here in exemplified manner the diode 413 of FIG. 5 is omitted.

The circuit of FIG. 7 essentially corresponds to that of FIG. 4, but the resistor R614′ is inserted between the control signal source 613 and diode D611. There is no resistor corresponding to resistor R314 in FIG. 4.

A further fundamental modification of the circuit according to FIG. 7 can consist of the diodes D612 and resistors R613 being interchanged compared with FIG. 4. Thus, the diodes D612 are directly at the source of the connecting switching signals 621.

A further, not shown variant of the circuit of FIG. 7 is designed in such a way that the diodes D612 are reversed. Therefore a diode D612 as the connecting means with a connecting switching signal 621 in the high time interval can connect the sensor element C613 to the remaining circuit.

The invention or the above-described circuits are characterized by the following points:

The circuit is subdivided into the control part, evaluating part and signal branch part. The number of signal branches can be essentially chosen at random and a larger number can be selected, e.g. up to 20 signal branches or sensor elements.

Of the numerous sensor branches through a corresponding connecting switching signal 21 and corresponding connecting means T12 or D12, in each case precisely one sensor branch is connected with a sensor element C13 to the control and evaluating means. Thus, a type of multiplexing can be brought about in a very simple manner. As a result of the shift of the voltage equilibrium at the transistor T11, with a corresponding charging of the capacitor C11 in the evaluating part, an analog output signal can be obtained. This output signal can be evaluated without further amplification by a controller or the like.

The possibility of varying the arrangement and design of the connecting switching means and the control thereof by connecting switching signals is rendered generally comprehensible and correspondingly implementable for the expert by the preceding description and the associated circuit examples.

It is possible to replace the capacitive sensor element C13 by a corresponding, different sensor element, e.g. optically or ultrasonically based and to correspondingly adapt the same to the circuit.

A major advantage of such a circuit layout is that its components can be reduced, which leads to cost savings and ensures a reliable function.

Thus, according to an embodiment of the invention, a circuit layout for several sensor elements of touch switches can be created. It is subdivided into a control part with a control signal and a sensor part with several sensor branches, in each case containing a capacitive sensor element. An evaluating part inter alia has a capacitor, where an analog output signal can be tapped. By means of connecting means, e.g. in the form of diode transistors, with corresponding control means precisely one sensor branch is connected to the remaining circuit and the corresponding sensor element is controlled and evaluated.

1. Circuit layout for several sensor elements of several touch switches, said sensor elements having an operating state that changes as a consequence of operation, said circuit layout comprising:
a control part for producing a control signal,
a sensor part including said sensor elements,
an evaluating part comprising evaluating means;
wherein connecting means are provided for a connection of at least one of said sensor elements with said evaluating part for evaluating said operating state of said sensor element.

2. Circuit layout according to claim 1, wherein said connection is selectable.

3. Circuit layout according to claim 1, wherein said connecting means are semiconductor components.

4. Circuit layout according to claim 3, wherein said connecting means are diodes.

5. Circuit layout according to claim 1, wherein said connecting means are switching means or switches.

6. Circuit layout according to claim 5, wherein said switches are electronically controllable switches.

7. Circuit layout according to claim 1, wherein said connecting means are controllable via a timed signal, the timing of said timed signal being such that in accordance with the number of said sensor elements in each case only one of said sensor elements is simultaneously connected via said connecting means to said evaluating part.

8. Circuit layout according to claim 1, wherein there is provided one connecting means per said sensor element.

9. Circuit layout according to claim 1, wherein said sensor elements are permanently connected to said control part.

10. Circuit layout according to claim 9, wherein said control signal is permanently applied to said sensor elements.

11. Circuit layout according to claim 1, wherein said sensor elements are connectable by further connecting means to said control part or said control signal.

12. Circuit layout according to claim 11, wherein said sensor elements are connectable by said further connecting elements in simultaneous manner to said control part and said evaluating part, said connecting means being controllable by means of a timed signal, the timing of said signal being such that in accordance with the number of said sensor elements in each case only one of said sensor elements is simultaneously connected via said connecting means to said evaluating part.

13. Circuit layout according to claim 1, wherein said evaluating part includes a capacitor and a transistor, wherein:
a transistor collector of said transistor is connected across said capacitor to ground,
a transistor emitter of said transistor is connected to said control signal,
a transistor base of said transistor is connected via a diode and a resistor to said control signal, and
said connected sensor element is in an unoperated state, an equilibrium being set between said base and said emitter across said resistor and said diode.

14. Circuit layout according to claim 13, wherein said evaluating part is connected to a controller for reading out an output signal of said evaluating part.

15. Circuit layout according to claim 13, wherein on operating said sensor element there is a modification to the equilibrium between said transistor emitter and said transistor base, and then said transistor further opens and said capacitor is charged to a higher voltage value.

16. Circuit layout according to claim 15, wherein said transistor is driven as a resistor, said transistor being controllable across its base.

17. Circuit layout according to claim 1, wherein said sensor elements are included in sensor branches with a control point and a body contact, said control signal being applied to said control point, and said evaluating circuit and said connecting means are included in said sensor branch.

18. Circuit layout according to claim 17, wherein in said sensor branch is included a control of said connecting means.
